(19) United States
(12) Patent Application Publication
(10) Pub. No.: US 2004/0152244 A1
(43) Pub. Date: Aug. 5, 2004

(54) Semiconductor device and its fabrication method

(76) Inventors: Hiroshi Yamamoto, Ibaraki (JP); Tsuyoshi Inoue, Ibaraki (JP); Mitsuru Yoshikawa, Ibaraki (JP); Saiki Hotate, Ibaraki (JP)

Correspondence Address: TEXAS INSTRUMENTS INCORPORATED, P O BOX 655474, M/S 3999, DALLAS, TX, 75265

(21) Appl. No.: 10/739,633

(22) Filed: Dec. 18, 2003

(30) Foreign Application Priority Data
Dec. 25, 2002 (JP) (2002)-375033

(51) Int. Cl. H01L 21/335

(52) U.S. Cl. 438/142

(57) ABSTRACT

A MOSFET semiconductor device and its fabrication method by which effects of parasitic transistors can be eliminated, subthreshold characteristic can be improved, and the threshold can be regulated easily. It has a configuration in which first semiconductor region 12 containing first-conductance type and second-conductance type impurities while functioning as the first-conductance type in effect is formed on a semiconductor substrate, isolation structure 23 is formed by means of an LOCOS method so as to separate active region AR, gate electrode 30 (G) is formed on first semiconductor region 12 via gate insulating film 24, second second-conductance type semiconductor region SD is formed on the surface layer part of first semiconductor region 12 at either side of the gate electrode, and first-conductance type channel stop edge regions (CSa and CSb) containing a higher concentration than first semiconductor region 12 are formed immediately below isolation structure 23 over the entire region in the width direction of bird's beak BB at the part in the region where gate electrode 30 (G) and edge (bird's beak BB) of isolation structure 23 overlap.

### FIELD OF THE INVENTION

The present invention pertains to a semiconductor device and its fabrication method. More specifically, it pertains to a semiconductor device involving a MOS field effect transistor and its fabrication method.

### BACKGROUND OF THE INVENTION

Transistors widely utilized for semiconductor devices, such as IC and LSI, are classified roughly into field effect transistors, such as n-channel MOS transistors and p-channel MOS transistors, and pnp type or npn type bipolar transistors.

For example, a semiconductor device containing high-voltage driving transistors and low-voltage driving transistors may be adopted as a driver for driving a liquid crystal display.

FIG. 10(A) is a plan view of a MOS field effect transistor adopted in the aforementioned semiconductor device, and FIG. 10(B) is a cross section along line X-X′ in FIG. 10(A). In addition, FIG. 11 is a cross section along line Y-Y′ in FIG. 10(A).

For example, first semiconductor region (p-type well) 12 containing both a p-type conductive impurity and an n-type conductive impurity while functioning as p-type in effect is formed on a semiconductor substrate, and isolation structure 23 is formed in element isolating region ISO by means of a LOCOS method so as to separate active region AR, including a channel formation region, in the first semiconductor region. Isolation structure 23 comprises a main part with a prescribed film thickness and an edge called a bird's beak BB thinner than the main part.

Gate insulating film 24 is formed on first semiconductor region 12, and gate electrode 30 (G) is formed on top of this layer as far as over isolation structure 23 across the active region.

A source-drain region (source-drain region SD) comprising n-type low-concentration impurity region 14 and high-concentration impurity region 15 is formed on the surface layer of first semiconductor region 12 on either side of gate electrode 30 (G).

n-channel MOS field effect transistor TRI with a channel formation region in the active region of first semiconductor region 12 is configured in the aforementioned manner.

Furthermore, channel stop 13 (CS) in first semiconductor region 12 and immediately below the main part of isolation structure 23 is formed so as to contain a higher concentration of p-type conductive impurity than first semiconductor region 12.

However, the n-channel MOS field effect transistor has a problem in that it demonstrates poor characteristics in the subthreshold region.

FIG. 12 shows current-voltage curves of the MOS field effect transistor, wherein the vertical axis indicates drain current I_{d}, and the horizontal axis indicates gate voltage V_{gs}.

Respective current-voltage curves obtained when back bias V_{bs} is changed from 0 V to −12 V, −2 V stepwise are shown in said figure.

As shown in FIG. 12, the current-voltage characteristic of the MOS field effect transistor is poor in that it follows a two-step curve in the subthreshold region. In particular, the characteristic degrades as the back bias increases.

In addition, FIG. 13 is a diagram in which current-voltage curve SP obtained from a simulation using the Speiss model is shown together with current-voltage curve EP obtained based on the actually measured data shown in FIG. 12 when the back bias is 0 V and −8 V.

As such, they differ from each other significantly in the subthreshold region. In particular, as shown in region Z, the greater the back bias becomes, the farther they are separated from each other.

This suggests that, because parasitic transistors which are not assumed in the Speiss model are on at lower voltages, the characteristic 2-step curve is generated.

The parasitic transistors which cause the poor characteristic in the subthreshold region are formed because the channel formation region for the n-channel MOS field effect transistor is formed in first semiconductor region (p-type well) 12 which contains both a p-type conductive impurity and an n-type conductive impurity while functioning as p-type in effect.

A method for forming the first semiconductor region (p-type well) 12 will be explained with reference to FIG. 14.

First, oxide film 20 is formed on the surface of p⁻⁻-type semiconductor substrate 10 by means of thermal oxidation processing, for example, as shown in FIG. 14(A). Then, as shown in FIG. 14(B), n-type conductive impurity ions DP1, such as phosphorus, are injected into the entire surface to form n-type well 11. Then, as shown in FIG. 14(C), resist mask PRa with a pattern used to create an opening for the p-type well is formed, and p-type conductive impurity ions DP2, such as boron, are injected deeper than n-type well 11 to form first semiconductor region (p-type well) 12.

First semiconductor region (p-type well) 12 formed in said manner contains both the p-type conductive impurity and the n-type conductive impurity while functioning as p-type in effect.

When an isolation structure is formed on first semiconductor region (p-type well) 12, which contains both the p-type conductive impurity and the n-type conductive impurity while functioning as p-type in effect, using the LOCOS method, the phosphorus as the n-type conductive impurity collects in the lower layer of the isolation structure, the concentration of the phosphorus increases, and the concentration of the p-type conductive impurity results in decreased effect.

A method for forming the isolation structure in first semiconductor region (p-type well) 12 using the LOCOS method will be explained with reference to FIG. 15.

As shown in FIG. 15(A), silicon oxide film 21 is first formed on the surface of first semiconductor region (p-type well) 12 by means of thermal oxidation processing, for example, silicon nitride film 22 is further formed using a CVD (Chemical Vapor Deposition) method, for example, and resist mask PRb with a pattern used to create an opening for element isolating region ISO while protecting active region AR as the channel formation region is formed on top of it.

Next, as shown in FIG. 15(B), pattern etching is applied to silicon nitride film 22 using resist mask PRb to remove silicon nitride film 22 in element isolating region ISO, and resist mask PRb is then removed.

Next, as shown in FIG. 15(C), after the conductive impurity such as boron for forming the channel stop in element isolating region ISO is ion-injected, oxidation is applied from the surface layer of first semiconductor region (p-type well) 12 in element isolating region ISO by means of wet oxidation using silicon nitride film 22 remaining in active region AR as a mask in order to form isolation structure 23 made of a silicon oxide thick film.

A main part with a prescribed thickness is formed in element isolating region ISO on isolation structure 23, and an edge called a bird's beak BB thinner than the main part is formed in such a manner that it extends below silicon nitride film 22 used as a mask during wet oxidation.

Subsequently, silicon nitride film 22 is removed.

As shown in the schematic cross section in FIG. 16, isolation structure 23 grows into active region AR to extend from element isolating region ISO, from which silicon nitride film 22 is removed, to an equal width W_{BB} of bird's beak BB. Although width W_{BB} of bird's beak BB is dependent also on the film thickness of the main part of bird's beak BB, it is approximately 0.5-0.6 μm.

As described above, as isolation structure 23 grows, the n-type impurity, such as phosphorus, contained in the semiconductor substrate in the region which becomes isolation structure 23 from the beginning travels in the direction of arrow M to the main part of isolation structure 23 and below bird's beak BB, and the concentration of the n-type impurity in region R immediately below the main part of isolation structure 23 and bird's beak BB increases, so that the effective concentration of the p-type impurity in said region R decreases. In the figure, effective p-type impurity concentration P1 in the active region and effective p-type impurity concentration P2 immediately below isolation structure 23 show the relationship expressed as P1>P2.

That is, because the effective p-type impurity concentration is decreased immediately below isolation structure 23, if a transistor is formed in said region, its threshold becomes lower than that of a transistor formed in a region where the effective p-type impurity concentration is not decreased.

In FIG. 10 and FIG. 11, the parts where bird's beak BB as the edge of isolation structure 23 and gate electrode 30 (G) overlap constitute parasitic transistors TR2a and TR2b with low threshold formed in the region where the effective p-type impurity concentration is decreased.

As described above, when parasitic transistors with a channel formation region are formed in first semiconductor region (p-type well) 12 in the regions where gate electrode 30 (G) and the edge (bird's beak BB) of isolation structure 23 overlap, the parasitic transistors turn on at lower voltages, resulting in a characteristic 2-step curve in terms of current versus voltage.

Adopting said MOS field effect transistor with a poor characteristic in the subthreshold region for a switching element creates problems of a large voltage amplitude and an increased power consumption.

In addition, because the threshold of parasitic transistors cannot be regulated, the characteristics of an n-channel MOS field effect transistor containing these parasitic transistors also fluctuate.

When the low-current region of said kind of transistor is used as an operational amplifier of an analog circuit, it becomes crucial to match threshold Vₜₕ in a differential pair or a current mirror circuit. However, because the parasitic transistors form, it is difficult to regulate threshold Vₜₕ to achieve sufficient matching, resulting in a deleterious effect, such as an increased offset voltage.

The present invention was conceived in light of the aforementioned situation, and the purpose of the present invention is to present a semiconductor device having a MOS field effect transistor in which the subthreshold characteristic is improved by eliminating the effect of parasitic transistors formed below the edge of an isolation structure in order to make it easy to regulate the threshold, as well as its fabrication method.

### SUMMARY OF THE INVENTION

In order to achieve the aforementioned goal, the semiconductor device of the present invention has a semiconductor substrate, a first semiconductor region which is formed on the semiconductor substrate and contains both a first-conductivity type impurity and a second-conductivity type impurity while functioning as the first-conductance type in effect, an isolation structure comprising a main part with a prescribed film thickness and an edge thinner than the main part which is formed so as to separate an active region, including a channel formation region, in the first semiconductor region, a gate electrode formed in the first semiconductor region via a gate insulating film in such a manner that it extends across the active region as far as over the isolation structure, a source-drain region of the second-conductance type formed on the surface part of the first semiconductor region at either side of the gate electrode, and channel stop edge regions which contain a higher concentration of first-conductivity type impurity than the first semiconductor region and are formed immediately below the isolation structure at least over the entire region in the width direction of the isolation structure at the part of the first semiconductor region where the gate electrode and the edge of the isolation structure overlap.

Because channel stop edge regions are formed where the gate electrode and the edge of the isolation structure overlap, and the threshold of parasitic transistors formed below the edge of the isolation structure is increased, the threshold of the MOS field effect transistor can be regulated easily by improving the subthreshold characteristic by eliminating the effect of the parasitic transistors formed below the edge of the isolation structure.

In the method for fabricating the semiconductor device of the present invention, a first semiconductor region containing both a first-conductivity type impurity and a second-conductivity type impurity while functioning as the first-conductance type in effect is formed on a semiconductor substrate. Next, an isolation structure comprising a main part with a prescribed film thickness and an edge thinner than the main part is formed so as to separate an active region, including a channel formation region, in the first semiconductor region, and a gate insulating film is formed on the first semiconductor region. Then, a gate electrode is formed on the gate insulating film in the first semiconductor region in such a manner that it extends across the active region as far as over the isolation structure, and a second second-conductance type semiconductor region is formed on the surface part of the first semiconductor region at either side of the gate electrode. The MOS field effect transistor is formed in the aforementioned manner.

### BRIEF DESCRIPTION OF THE DRAWINGS

FIG. 1(A) is a plan view of the MOS field effect transistor mounted on the semiconductor device pertaining to the present embodiment, and FIG. 1(B) is a cross section along line X-X′ in FIG. 1(A).

FIG. 2 is a cross section along line Y-Y′ in FIG. 1(A).

FIG. 3 is a cross section illustrating the method for fabricating the semiconductor device pertaining to the first embodiment.

FIGS. 4(A) and (B) are cross sections illustrating the fabrication steps in the method for fabricating the semiconductor device pertaining to the first embodiment; wherein, (A) is a cross section along line X-X′ in FIGS. 1(A), and (B) is a cross section along line Y-Y′.

FIGS. 5(A) and (B) are cross sections illustrating the fabrication steps in the method for fabricating the semiconductor device pertaining to the first embodiment; wherein, (A) is a cross section along line X-X′ in FIGS. 1(A), and (B) is a cross section along line Y-Y′.

FIG. 6(A) is a plan view of the MOS field effect transistor mounted on the semiconductor device pertaining to the present embodiment, and FIG. 6(B) is a cross section along line Y-Y′ in FIG. 6(A).

FIG. 7(A) is a plan view of the MOS field effect transistor mounted on the semiconductor device pertaining to the present embodiment, and FIG. 7(B) is a cross section along line X-X′ in FIG. 7(A).

FIG. 8 is a graph in which current-voltage curve EX of the MOS field effect transistor pertaining to Embodiment example 1 is shown together with current-voltage curve CP of the field effect transistor pertaining to the conventional example for comparison.

FIG. 9 is a graph in which current-voltage curve SP obtained from a simulation using the Speiss model is shown together with current-voltage curve EP based on the actually measured data shown in FIG. 8.

FIG. 10(A) is a plan view of the MOS field effect transistor pertaining to the conventional example, and FIG. 10(B) is a cross section along line X-X′ in FIG. 10(A).

FIG. 11 is a cross section along line Y-Y′ in FIG. 10(A).

FIG. 12 shows the current-voltage curve of the MOS field effect transistor pertaining to the conventional example.

FIG. 13 is a diagram in which the current-voltage curve obtained from a simulation using the Speiss model is shown together with the current-voltage curve based on the actually measured data.

FIG. 14(A) through (C) are cross sections showing the method for forming the first semiconductor region (p-type well).

FIG. 15(A) through (C) are cross sections showing the method for forming the isolation structure in the first semiconductor region (p-type well) using the LOCOS method.

FIG. 16 is a schematic cross section for illustrating the phenomenon which occurs during the isolation structure formation step.

### REFERENCE NUMERALS AND SYMBOLS AS SHOWN IN THE DRAWINGS

In the figures, 10 represents a p⁻⁻-type semiconductor substrate, 11 an n-type well, 12 a p-type well (first semiconductor region), 13, a CS channel stop region, 13a (CSa), 13b (CSb) a channel stop edge region, 14 a low-concentration impurity region, 15 a high-concentration impurity region, 16 a low-concentration impurity region, 17 a high-concentration impurity region, 20 an oxide film, 21 a silicon oxide film, 22 a silicon nitride film, 23 an isolation structure, 24 a gate insulating film, 25 a first sidewall, 26 a second sidewall, 30, G a gate electrode, AR an active region, ISO an element isolating region, SD a source-drain region, BB a bird's beak, TR, TR1 an n-channel MOS field effect transistor, and TR2a, TR2b a parasitic transistor.

### DESCRIPTION OF THE EMBODIMENTS

Embodiments of the semiconductor device and its fabrication method of the present invention will be explained with reference to figures.

First Embodiment

The semiconductor device pertaining to the present embodiment has a MOS field effect transistor.

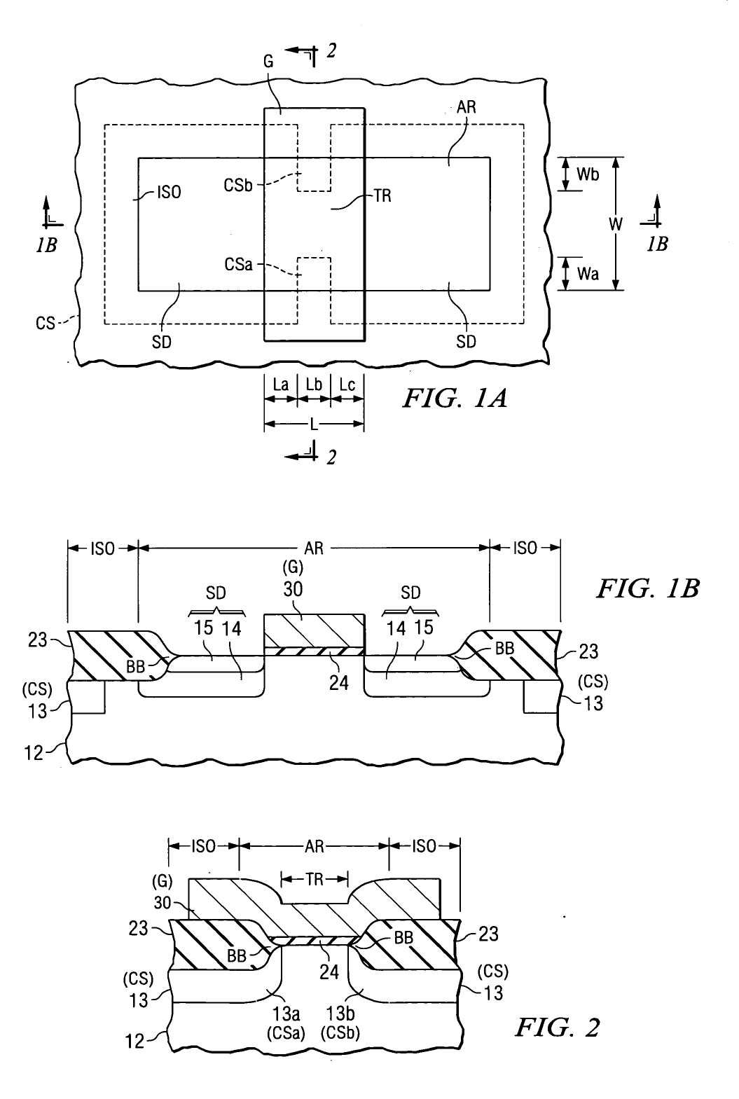

FIG. 1(A) is a plan view of the MOS field effect transistor mounted on the semiconductor device pertaining to the present embodiment, and FIG. 1(B) is a cross section along line X-X′ in FIG. 1(A). In addition, FIG. 2 is a cross section along line Y-Y′ in FIG. 1.

For example, first semiconductor region (p-type well) 12 containing both a p-type (first-conductance type) conductive impurity and an n-type (second-conductance type) conductive impurity while functioning as the first-conductance type in effect is formed on a semiconductor substrate.

First semiconductor region (p-type well) 12 is formed by introducing the p-type conductive impurity from the semiconductor substrate surface into a region deeper than the n-type well in the n-type well region formed over the entire surface of a p⁻⁻-type semiconductor substrate.

First semiconductor region (p-type well) 12 formed in said manner contains both the p-type conductive impurity and the n-type conductive impurity while functioning as p-type in effect.

Isolation structure 23 is formed in the first semiconductor by means of an LOCOS method so as to separate active region AR, including a channel formation region. Isolation structure 23 has a main part with a prescribed film thickness and an edge called a bird's beak BB thinner than the main part.

Gate insulating film 24 is formed on first semiconductor region 12, and gate electrode 30 (G) is formed on top of this layer as far as over isolation structure 23 across the active region.

A source-drain region (SD) comprising n-type low-concentration impurity region 14 and high-concentration impurity region 15 is formed on the surface layer part of first semiconductor region 12 on either side of gate electrode 30 (G).

n-channel MOS field effect transistor TR having the channel formation region in the active region of first semiconductor region 12 is configured in said manner.

Here, in the semiconductor device pertaining to the present embodiment, channel stop edge regions (13a (CSa) and 13b (CSb)) containing a higher concentration of p-type conductive impurity than first semiconductor region 12 are formed immediately below isolation structure 23 over the entire region at least in the width direction of the edge (bird's beak BB) of isolation structure 23 to part of the first semiconductor region 12 where gate electrode 30 (G) and the edge (bird's beak BB) of isolation structure 23 overlap.

Furthermore, channel stop region 13 (CS) is formed in such a manner that a higher concentration of p-type conductive impurity than first semiconductor region 12 is contained in first semiconductor region 12 immediately below the main part of isolation structure 23.

In the present embodiment, channel stop edge regions (13a (CSa) and 13b (CSb)) and channel stop region 13 (CS) are formed as one unit.

In the case of the MOS field effect transistor of the semiconductor device pertaining to the present embodiment described above, parasitic transistors having the channel formation region in first semiconductor region 12 and a threshold lower than that of n-channel MOS field effect transistor TR as a result are formed in the region where gate electrode 30 (G) and the edge (bird's beak BB) of isolation structure 23 overlap. However, because channel stop edge regions (13a (CSa) and 13b (CSb)) containing a high concentration of p-type conductive impurity are formed over the entire region at least in the width direction of the edge of the isolation structure, the threshold of the parasitic transistors is increased to eliminate the effect of the parasitic transistors, and the subthreshold characteristic can be improved to make it easy to regulate the threshold of the MOS field effect transistor.

In FIG. 1(A), gate width W (equivalent to the width of active region AR and includes the width of the bird's beak) is 1.8-20 μm, for example. Here, because the width of bird's beak BB extending into active region AR is approximately 0.5-0.6 μm, widths Wa and Wb of channel stop edge regions (13a (CSa) and 13b (CSb)) extending in the width direction of the gate as opposed to the active region are set to approximately 0.6 μm.

In addition, due to the design of the transistor, gate length L is set to 1.2-4 μm, for example. Length Lb of channel stop edge regions (13a (CSa) and 13b (CSb)) in the direction of the gate length and lengths La and Lc other than channel stop edge regions are La=0.4 μm, Lb=2.2 μm, and Lc=0.4 μm when gate length L is 3.0 μm. In addition, when gate length L is 1.2 μm, La=0.4 μm, Lb=0.4 μm, and Lc=0.4 μm.

Channel stop edge regions (13a (CSa) and 13b (CSb)) are formed over the entire region at least in the width direction of the edge (bird's beak BB) of isolation structure 23 in the region where gate electrode 30 (G) and the edge (bird's beak BB) of isolation structure 23 overlap at a part of first semiconductor region 12. When the channel stop edge regions are provided in the aforementioned manner, the threshold of the parasitic transistors can be increased sufficiently.

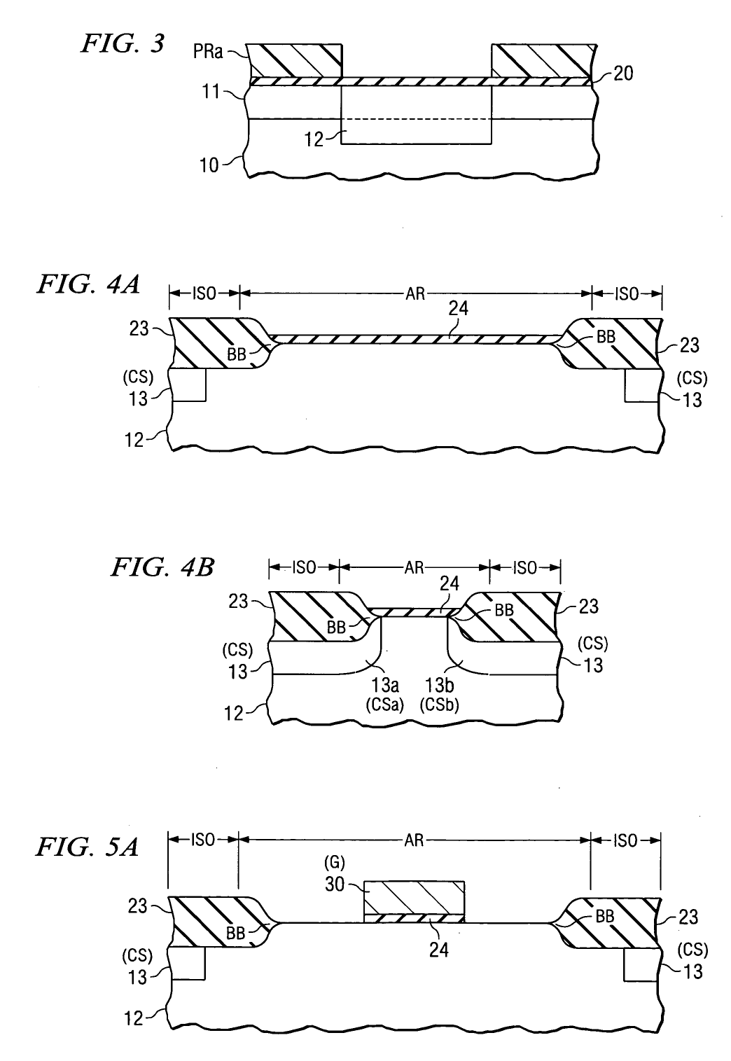

The method for fabricating the semiconductor device pertaining to the present embodiment will be explained with reference to the cross sections in FIG. 3 through FIG. 5.

First, as shown in FIG. 3, after n-type well 11 is formed by injecting ions of an n-type conductive impurity such as phosphorus into the entire surface of p⁻⁻-type semiconductor substrate 10, for example, ions of a p-type conductive impurity such as boron are injected deeper than the n-type well into a p-type well formation region opened selectively using resist mask PRa in order to form first semiconductor region (p-type well) 12.

Next, as shown in FIGS. 4(A) and (B) ((A) is a cross section along line X-X′ in FIGS. 1(A), and (B) is a cross section along line Y-Y′), isolation structure 23 comprising a main part with a prescribed thickness and an edge (bird's beak BB) thinner than the main part is formed so as to separate active region AR, including a channel formation region, in first semiconductor region (p-type well) 12, and gate insulating film 24 is formed in first semiconductor region (p-type well) 12.

Here, as shown in FIGS. 4(A) and (B), before the isolation structure is formed, channel stop edge regions (13a (CSa) and 13b (CSb)) containing a higher concentration of first-conductivity type impurity than the first semiconductor region are formed over the entire region at least in the width direction of the edge of the isolation structure at the part of first semiconductor region (p-type well) 12 in the region where gate electrode 30 (G) and the edge (bird's beak BB) of isolation structure 23 overlap, that is, the region formed immediately below the isolation structure once the isolation structure is formed.

It is desirable that, when forming the channel stop edge regions (13a (CSa) and 13b (CSb)), channel stop region 13 (CS) containing a higher concentration of p-type conductive impurity than the first semiconductor region is formed at the same time in the region of first semiconductor region (p-type well) 12 to be formed immediately below the main part of the isolation structure once isolation structure 23 is formed. When they are formed simultaneously, the number of masks to be used can be prevented from increasing.

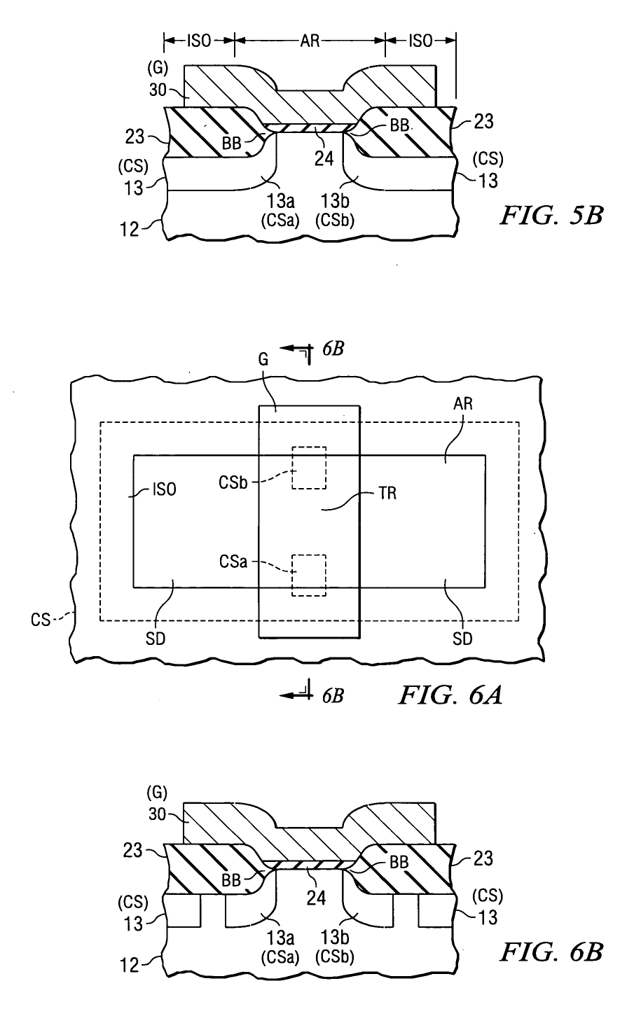

Next, as shown in FIGS. 5(A) and (B) ((A) is a cross section along line X-X′ in FIGS. 1(A), and (B) is a cross section along line Y-Y′), gate electrode 30 (G) is formed on top of gate insulating film 24 in first semiconductor region (p-type well) 12 as far as over isolation structure 23 across active region AR.

Next, a source-drain region (source-drain region SD) comprising n-type low-concentration impurity region 14 and high-concentration impurity region 15 is formed on the surface layer part of first semiconductor region (p-type well) 12 on either side of gate electrode 30 (G). This completes the fabrication of the semiconductor device pertaining to the present embodiment shown in FIG. 1 and FIG. 2.

In the method for fabricating the semiconductor device pertaining to the present embodiment, because channel stop edge regions (13a (CSa) and 13b (CSb)) are formed, the threshold of the parasitic transistors having the channel formation region in first semiconductor region (p-type well) 12 in the region where gate electrode 30 (G) and the edge (bird's beak BB) of isolation structure 23 overlap can be increased to eliminate the effect of the parasitic transistors formed below the isolation structure, so that the subthreshold characteristic can be improved to make it easy to regulate the threshold of the MOS field effect transistor.

Second Embodiment

FIG. 6(A) is a plan view of the MOS field effect transistor mounted on the semiconductor device pertaining to the present embodiment, and FIG. 6(B) is a cross section along line Y-Y′ in FIG. 6(A).

As shown in FIG. 6(B), the MOS field effect transistor of the semiconductor device pertaining to the present embodiment is different in that the channel stop edge regions (13a (CSa) and 13b (CSb)) and channel stop region 13 (CS) are formed individually instead of as one unit in the cross section along line Y-Y′ in FIG. 6(A). The rest is identical substantially to that of the semiconductor device of the first embodiment.

In the case of the MOS field effect transistor of the semiconductor device pertaining to the present embodiment described above, like in the first embodiment, parasitic transistors having the channel formation region in first semiconductor region 12 and a threshold lower than that of n-channel MOS field effect transistor TR as a result are formed in the region where gate electrode 30 (G) and the edge (bird's beak BB) of isolation structure 23 overlap. However, because the channel stop edge regions (13a (CSa) and 13b (CSb)) containing a high concentration of p-type conductive impurity are formed over the entire region at least in the width direction of the edge of the isolation structure, the threshold of the parasitic transistors is increased to eliminate the effect of the parasitic transistors, and the subthreshold characteristic can be improved to make it easy to regulate the threshold of the MOS field effect transistor.

Although the method for fabricating the semiconductor device pertaining to the present embodiment is substantially identical to that of the first embodiment, channel stop edge regions (13a (CSa) and 13b (CSb)) and channel stop region 13 (CS) are formed individually instead of as one unit.

It is sufficient that channel stop edge regions (13a (CSa) and 13b (CSb)) are formed over the entire region at least in the width direction of the isolation structure in the region where gate electrode 30 (G) and the edge (bird's beak BB) of isolation structure 23 overlap.

Furthermore, in this case like in the first embodiment, it is desirable that channel stop edge regions (13a (CSa) and 13b (CSb)) and channel stop region 13 (CS) are formed simultaneously. When they are formed simultaneously, an increase in the number of masks to be used can be prevented.

Third Embodiment

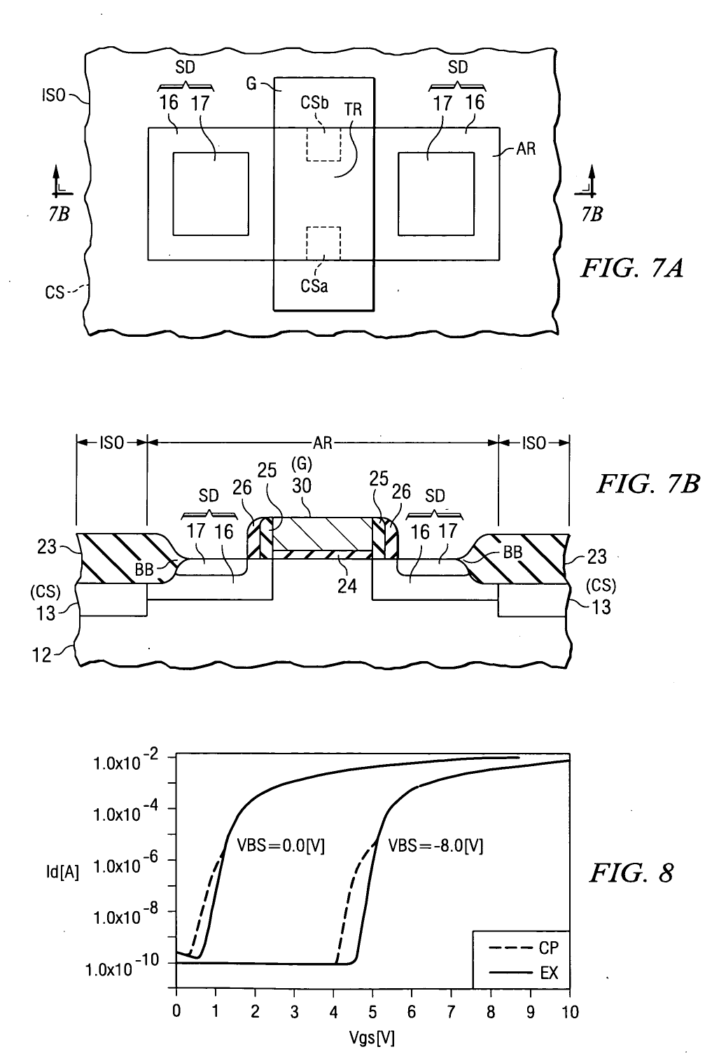

FIG. 7(A) is a plan view of the MOS field effect transistor mounted on the semiconductor device pertaining to the present embodiment, and FIG. 7(B) is a cross section along line X-X′ in FIG. 7(A). The cross section along line X-X′ in FIG. 7(A) is similar to the cross section in FIG. 2 in the first embodiment.

The MOS field effect transistor of the semiconductor device pertaining to the present embodiment is different in that the source-drain region (source-drain region SD) comprises n-type low-concentration impurity region 16 and high-concentration impurity region 17, and it adopts a DDD (Double Diffused Drain) structure in which low-concentration impurity region 16 and high-concentration impurity region 17 are offset. In the case of said DDD structure, sidewalls are formed on either side of gate electrode 30 (G). In addition, as shown in the figure, said sidewalls may be realized using a double sidewall structure comprising first sidewall 25 and second sidewall 26. While channel stop region 13 (CS) is formed over the entire region below isolation structure 23 except where bird's beaks BB are present, this structure can be adopted because a pressure resistance can be attained due to the fact that high-concentration impurity region 17 is formed inside of low-concentration impurity region 16.

It is identical to the first embodiment with the exception of the aforementioned points.

In the semiconductor device pertaining to the present embodiment, channel stop edge regions (13a (CSa) and 13b (CSb)) containing a higher concentration of p-type conductive impurity than first semiconductor region 12 are formed over the entire region at least in the width direction of the edge (bird's beak BB) of the isolation structure 23 immediately below isolation structure 23 at the part of first semiconductor region 12 in the region where gate electrode 30 (G) and the edge (bird's beak BB) of isolation structure 23 overlap.

In the case of the MOS field effect transistor of the semiconductor device pertaining to the present embodiment described above, like in the first embodiment, parasitic transistors having the channel formation region in first semiconductor region 12 and the threshold lower than that of n-channel MOS field effect transistor TR as a result form in the region where gate electrode 30 (G) and the edge (bird's beak BB) of isolation structure 23 overlap. However, because channel stop edge regions (13a (CSa) and 13b (CSb)) containing a high concentration of p-type conductive impurity are formed over the entire region at least in the width direction of the edge of the isolation structure, the threshold of the parasitic transistors is increased to eliminate the effect of the parasitic transistors, the subthreshold characteristic can be improved to make it easy to regulate the threshold of the MOS field effect transistor.

Although the method for fabricating the semiconductor device pertaining to the present embodiment is substantially identical to that of the first embodiment, because the DDD is adopted, a mask, such as a resist mask, to be used during the impurity ion-injection step for forming high-concentration impurity region 17 must be created.

In addition, channel stop region 13 (CS) is formed over the entire region below isolation structure 23 except where bird's beaks BB are present. In such case, it is also desirable that channel stop edge regions (13a (CSa) and 13b (CSb)) and channel stop region 13 (CS) are formed simultaneously. When they are formed simultaneously, an increase in the number of masks to be used can be prevented.

### EMBODIMENT EXAMPLE 1

FIG. 8 is a graph showing current-voltage curve EX obtained when the MOS field effect transistor pertaining to the first embodiment was actually formed and its current-voltage characteristic was measured, together with current-voltage curve CP obtained from the field effect transistor pertaining to the conventional example for comparison in which the parasitic transistors remain present when the back bias was 0 V and −8 V. The vertical axis indicates drain current I_{d}, and the horizontal axis indicates gate voltage V_{gs}.

Here, in the MOS field effect transistor formed, values L, La, Lb, Lc, W, Wa, and Wb in FIG. 1 were set as L=1.8 μm, La=0.6 μm, Lb=0.6 μm, Lc=0.6 μm, W=50 μm, Wa=0.6 μm, and Wb=0.6 μm.

As shown in FIG. 8, the current-voltage characteristic of the MOS field effect transistor change from a characteristic curve of 2 steps to a characteristic curve of 1 step when channel stop edge regions (13a (CSa) and 13b (CSb)) were provided, confirming that the characteristic was improved in the subthreshold region to eliminate the effect of the parasitic transistors.

### EMBODIMENT EXAMPLE 2

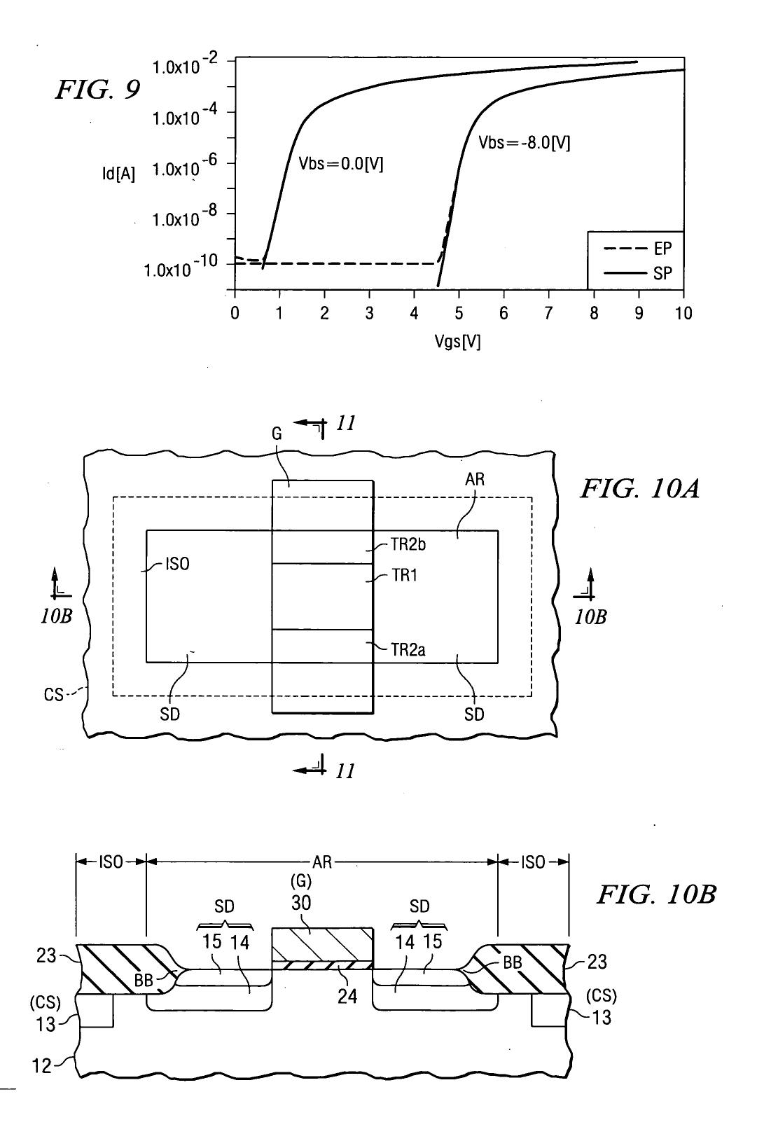

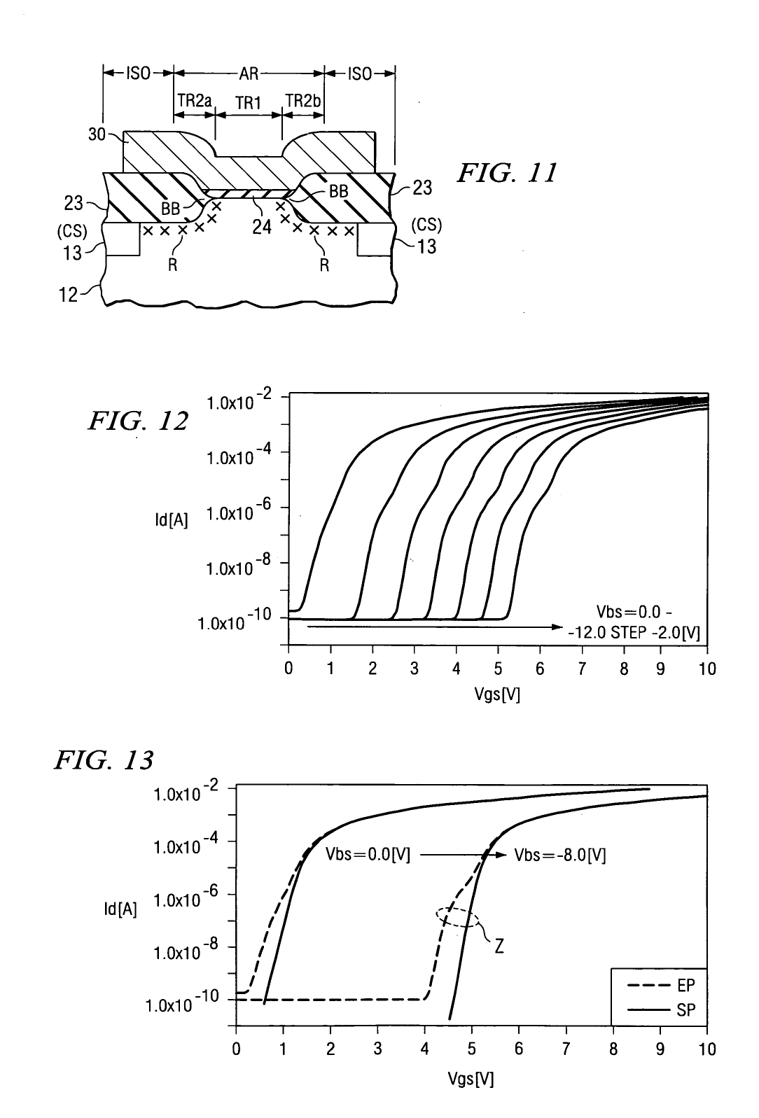

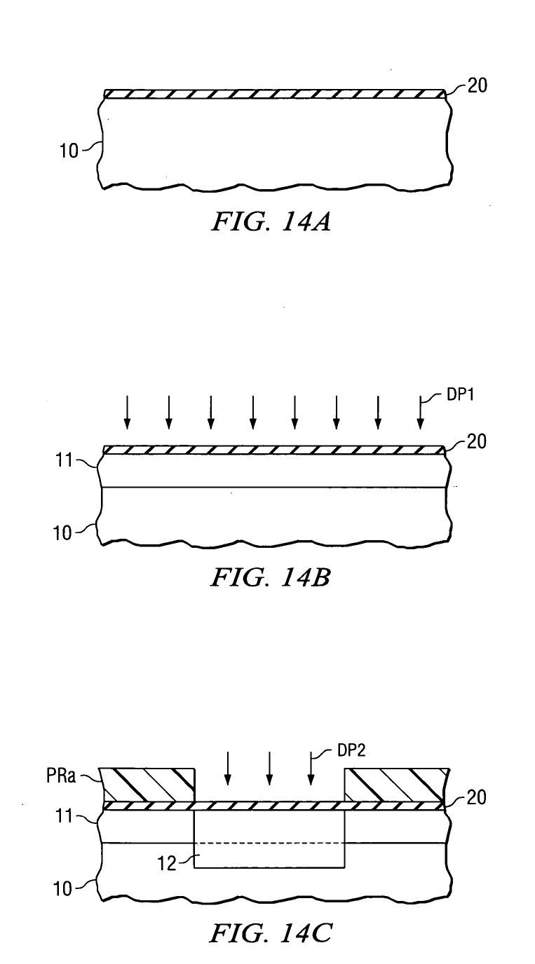

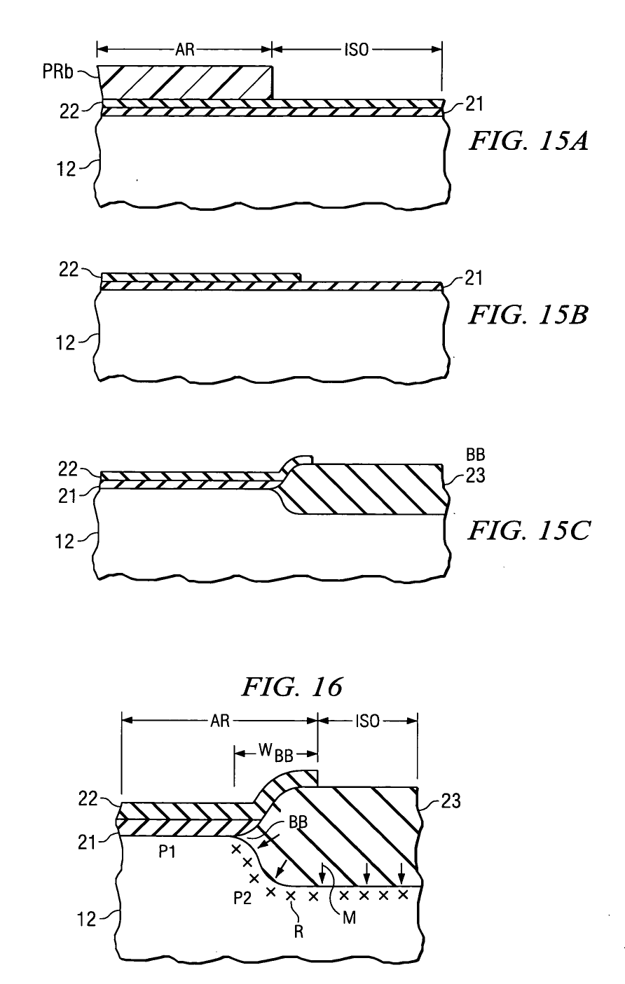

FIG. 9 is a graph showing current-voltage curve SP obtained from the MOS field effect transistor described in Embodiment Example 1 based on a simulation using the Speiss model together with current-voltage curve EP based on the actually measured data shown in FIG. 8 when the back bias was 0 V and −8 V.

It indicates that as the current-voltage curve changes to a characteristic curve of 1 step to improve the characteristic in the subthreshold region, the data obtained from the simulation and the actually measured data match, and the MOS field effect transistor of the present embodiment takes a configuration which can be explained using the Speiss model.

In addition, because it matches well with the Speiss model, a MOS field effect transistor with a characteristic close to the actual characteristic can be designed easily using a simulation based on the Speiss model.

### EMBODIMENT EXAMPLE 3

When the low-current region of the MOS field effect transistor of the semiconductor device pertaining to the respective embodiments described above was utilized as an operational amplifier for an analog circuit, threshold Vₜₕ in a differential pair or a current mirror circuit was able to be matched sufficiently, and the offset voltage in the high input voltage region or the high output amplitude region which depended on the characteristic of the n-channel MOS field effect transistor can be reduced to approximately 1/2 of that of the prior art.

The present invention can be well applied as a semiconductor device mounted with both a high-voltage driving transistor and a low-voltage driving transistor, a transistor for a power amplifier or an operational amplifier, or as a semiconductor device serving as a driver for driving a liquid crystal display.

The semiconductor device of the present invention is not restricted to the aforementioned embodiments.

For example, there is no restriction in terms of the arrangement of the n-type well and the p-type well as long as the first semiconductor region where the transistor is to be formed contains both the n-type impurity and the p-type impurity.

In addition, various kinds of conventional materials and structures may be adopted for the gate electrode material and the source-drain region structure.

Other modifications of various kinds can also be made without going beyond the gist of the present invention.

With the semiconductor device of the present invention, the threshold of the MOS field effect transistor can be regulated easily by improving the subthreshold characteristic by eliminating the effect of the parasitic transistors which form below the edge of the isolation structure.

With the semiconductor device fabrication method of the present invention, a MOS field effect transistor in which its threshold can be regulated easily by improving the subthreshold characteristic by eliminating the effect of the parasitic transistors which form below the edge of the isolation structure can be fabricated.

1. A semiconductor device comprising:
a semiconductor substrate,
a first semiconductor region located on the semiconductor substrate and comprising both a first-conductivity type impurity and a second-conductivity type impurity while functioning as the first-conductance type in effect,
an isolation structure comprising a main part with a prescribed film thickness and an edge thinner than the main part located in the first semiconductor region,
a gate electrode formed over the first semiconductor region and extending across the active region as far as over the isolation structure,
a source-drain region of the second conductance type formed in the first semiconductor region at either side of the gate electrode, and
channel stop edge regions containing a higher concentration of the first-conductivity type impurity than the first semiconductor region and which are formed immediately below the edge of the isolation structure where the gate electrode and the edge of the isolation structure overlap.

2. The semiconductor device described in claim 1 further comprising a channel stop region having a higher concentration of first-conductivity type impurity than the first semiconductor region and located in the first semiconductor region immediately below the main part of the isolation structure.

3. The semiconductor device described in claim 2 wherein the channel stop edge regions and the channel stop region are formed as one unit.

4. A method for fabricating a semiconductor device comprising the following steps:
forming a first semiconductor region comprising both a first-conductivity type impurity and a second-conductivity type impurity while functioning as the first-conductance type in effect on a semiconductor substrate;
forming an isolation structure comprising a main part with a prescribed film thickness and an edge thinner than the main part in the first semiconductor region;
forming a gate insulating film on the first semiconductor region,
forming a gate electrode on the gate insulating film in such a manner that it extends across an active region as far as over the isolation structure, and
forming a source-drain region of the second-conductance type in the first semiconductor region at either side of the gate electrode; and
forming channel stop edge regions containing a higher concentration of first-conductivity type impurity than the first semiconductor region in the regions immediately below the isolation structure at least over the entire region in the width direction of the isolation structure at the part of the first semiconductor region where the gate electrode and the edge of the isolation structure overlap after the isolation structure is formed, wherein the step of forming the channel stop edge regions is performed prior to the isolation structure formation step.

5. The method for fabricating a semiconductor device described in claim 4 further comprising the step of forming a channel stop region containing a higher concentration of first-conductivity type impurity than the first semiconductor region in the part of the first semiconductor region immediately below the main part of the isolation structure simultaneously with forming the channel stop edge region.

6. The method for fabricating a semiconductor device described in claim 4 wherein the step in which the first semiconductor region is formed on the semiconductor substrate includes a step in which a second-conductance type well is formed in the semiconductor substrate and a step in which the first-conductivity type impurity is introduced within well region from the surface of the semiconductor substrate to a region deeper than the well.

7. A semiconductor device having
a semiconductor substrate,
a semiconductor layer which is formed on the primary plane of the semiconductor substrate and contains a first-conductivity type impurity and a second-conductivity type impurity while functioning as the first-conductance type in effect,
an isolation structure formed on the semiconductor layer so as to define a prescribed active region on the primary plane of the semiconductor layer,
a gate electrode formed on the semiconductor layer via a gate insulating film across the active region,
first and second source-drain regions of the second-conductance type formed on the primary plane of the semiconductor layer in the active region while separated from each other across the gate electrode, and
channel stop edge regions of the first-conductance type with a higher impurity concentration than the semiconductor layer which are formed on the primary plane of the semiconductor layer placed below bird's beak regions of the isolation structure in the region where the gate electrode is formed above the isolation structure.

8. The semiconductor device described in claim 7 in which the channel stop edge regions are formed over the entire region in the width direction of the bird's beak region and at a part in the length direction of the gate electrode.

9. The semiconductor device described in claim 7 in which the first and second source-drain regions have a DDD (Double Diffused Drain) structure involving a first diffused region of the second-conductance type and a second diffused region of the second-conductance type with a higher impurity concentration than the first diffused region.

10. The semiconductor device described in claim 7 in which a channel stop region of the first-conductance type with a higher impurity concentration than the semiconductor layer formed on the primary plane of the semiconductor layer placed below the isolation structure is provided.

11. The semiconductor device described in claim 10 in which the channel stop edge regions and the channel stop region are formed as one unit.
